(19) United States
(12) Patent Application Publication
(10) Pub. No.: US 2004/0068685 A1
(43) Pub. Date: Apr. 8, 2004

(54) Simulation system and method for testing IDE channels

(76) Inventors: Ming Huan Yuan, Tu-chen (TW); Chia Yuan Liu, Tu-chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/335,384

(22) Filed: Dec. 30, 2002

(30) Foreign Application Priority Data
Oct. 4, 2002 (TW) 91122980

(51) Int. Cl. G01R 31/317

(52) U.S. Cl. 714/741

(57) ABSTRACT

A simulation system for testing IDE channels includes a testing board (100), a tested board electrically connected to the testing board and having at least an IDE chip with IDE channels to be tested, and a firmware having testing programs embedded therein. The firmware is electrically connected to the tested board in advance. The testing board has an IDE interface (101) for electrically connecting with the tested board, a buffer (102) for storing data temporarily, and a decoder (103) for decoding IDE commands. A simulation method for testing IDE channels includes acts of providing the above-mentioned components and executing the testing programs embedded in the firmware.

### BACKGROUND OF THE INVENTION

1. Field of the Invention

The present invention relates to a simulation system and method for testing integrated drive electronics (IDE) channels.

2. Description of Related Art

An IDE chip, such as an IDE controller, is a device which is mounted on a computer motherboard, and which controls the flow of data traffic between the main memory of a computer system and one or more peripheral devices electrically connected to the computer system via the IDE controller. One such peripheral device, for example, is an IDE disk drive. When employed in a personal computer system, an IDE controller must operate with many different types of IDE devices, such as hard disk drives, CD ROMs, and other devices. A typical IDE controller has at least two IDE channels: a primary IDE channel and a secondary IDE channel, both of which must operate effectively to ensure that the IDE controller functions for its intended purpose. Therefore, it is necessary to test the IDE channels before shipment.

U.S. Pat. No. 5,832,418 issued on Nov. 3, 1998, U.S. Pat. No. 6,006,166 issued on Dec. 21, 1999, and U.S. Pat. No. 6,076,180 issued on Jun. 13, 2000, all issued to Meyer and assigned to Micron Electronics, respectively disclose prior art apparatus and methods for testing IDE channels. These prior art apparatus for testing IDE channels are called test benches, which are simulated in a computer system by software modules written in Very High Definition Language (VHDL). The methods for testing IDE channels comprise acts of providing and executing the software modules mentioned above. Because the test algorithm is constructed in VHDL programming language, specialists must accomplish program such software modules. Furthermore, an additional computer operating system is needed for executing the testing software. Therefore, a simple and low-cost system and method for testing IDE channels is desired.

### SUMMARY OF THE INVENTION

It is an object of the present invention to provide a simple and low-cost system and method for testing IDE channels.

In order to achieve the object set forth, a simulation system for testing IDE channels includes a testing board, a tested board, and a firmware. The testing board comprises at least an IDE interface, a buffer, and a decoder. The IDE interface exchanges data with and receives control signals from the tested board. The buffer stores data temporarily. The decoder decodes control signals. At least a data bus is electrically connected between the IDE interface and the buffer for transmitting data therebetween. At least a control bus is electrically connected between the IDE interface and the decoder for transmitting control signals to the decoder. The buffer is controlled by the decoder with write or read signal. The tested board is electrically connected to the testing board via the IDE interface. The tested board has at least an IDE chip with at least one IDE channel to be tested. The firmware has embedded testing programs, and the firmware is electrically connected to the tested board in advance.

A simulation method in accordance with the present invention comprises the acts of: (1) providing a testing board having at least an IDE interface, a buffer, and a decoder for decoding IDE commands; (2) providing a tested board electrically connected to the testing board, the tested board having at least an IDE chip with one or more IDE channels to be tested; (3) providing a firmware having embedded testing programs therein, and the firmware is electrically connected to the tested board in advance; and (4) executing the testing programs.

Other objects, advantages and novel features of the invention will become more apparent from the following detailed description when taken in conjunction with the accompanying drawings.

### BRIEF DESCRIPTION OF THE DRAWINGS

FIG. 1 is a block diagram of a testing board in accordance with the present invention.

FIG. 2 is a flowchart illustrating the process of testing a particular IDE channel, in accordance with the present invention.

### DETAILED DESCRIPTION OF THE INVENTION

Reference will now be made in detail to the preferred embodiment of the present invention.

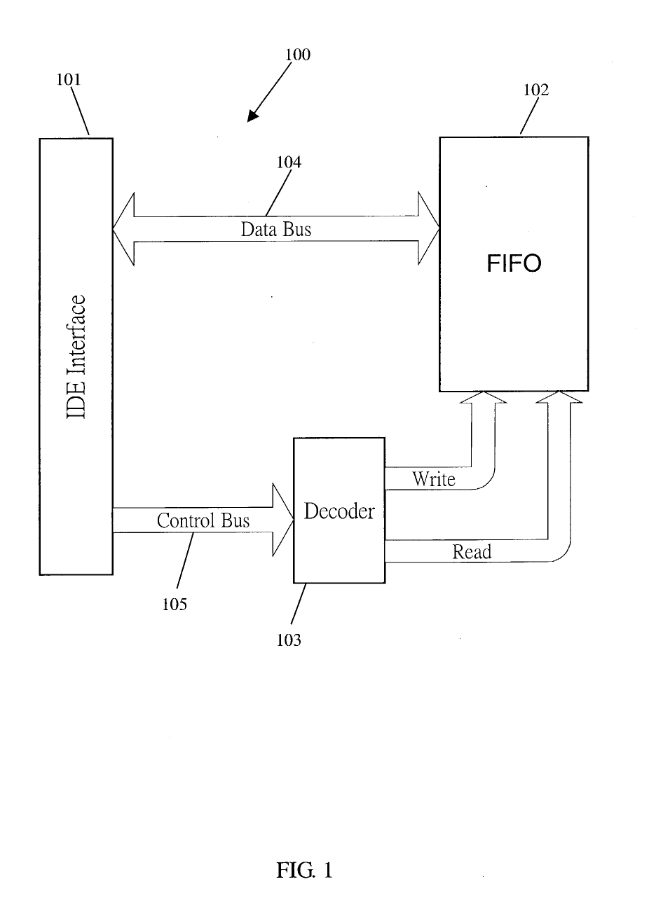

Referring to FIG. 1, a simulation system for testing an IDE channel in accordance with the present invention includes a testing board 100, a tested board (not shown), and a firmware (not shown).

The testing board 100 includes at least an IDE interface 101, for exchanging data with and receiving control signals from the tested board; a buffer, for storing data temporarily, wherein the buffer is a FIFO (First-In First-Out) buffer 102; and a decoder 103, for decoding control signals, such as IDE commands, such as a read or write computing commands. At least a data bus 104 is electrically connected between the IDE interface 101 and the FIFO buffer 102, for transmitting data therebetween. At least a control bus electrically connects the IDE interface 101 to the decoder 103, for transmitting control signals to the decoder 103 to control the operation of the FIFO buffer 102. When an IDE write computing command is converted by the decoder 103, and is received by the FIFO buffer 102, the FIFO buffer 102 accepts data transferred from the IDE interface 101 via the data bus 104, and stores the data temporarily therein. When an IDE read computing command is converted by the decoder 103 and received by the FIFO buffer 102, the FIFO buffer 102 sends data stored therein to the IDE interface 101 via the data bus 104.

The tested board is electrically connected to the testing board 100 via the IDE interface 101, and data are transferred between the tested board and the testing board 100 via the IDE interface 101. The tested board includes at least an IDE chip mounted thereon, and the IDE chip has at least an IDE channel to be tested.

The firmware has testing programs embedded therein is electrically connected to the tested board before a testing procedure. During the testing procedure, the firmware executes the testing programs for testing IDE channels of the IDE chip.

A method in accordance with the present invention by which the simulation system tests an IDE channel includes the acts of: (1) providing the testing board 100, wherein the testing board 100 has the IDE interface 101, the FIFO buffer 102, and the decoder 103 for decoding IDE commands; (2) providing the tested board and electrically connecting the tested board to the testing board 100 via the IDE interface 101, wherein the tested board has at least an IDE chip with at least an IDE channel to be tested; (3) providing the firmware with testing programs embedded therein, wherein the firmware is electrically connected to the tested board in advance; and (4) executing the testing programs.

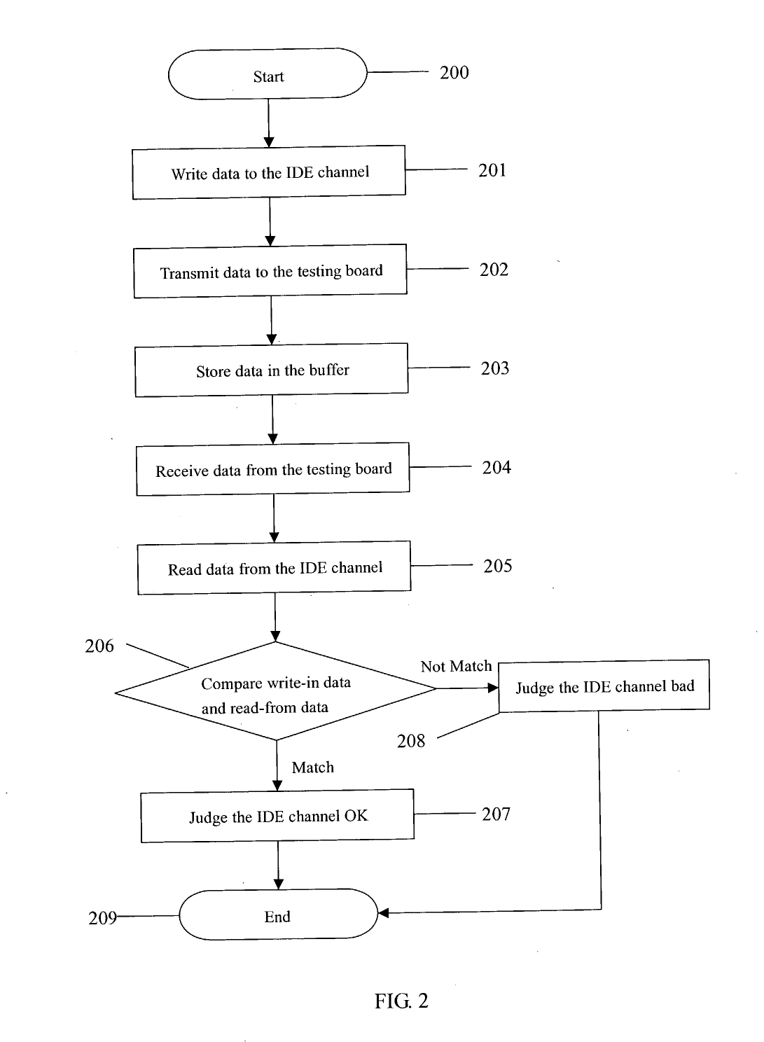

Referring to FIG. 2, a flowchart of the execution of the testing programs in accordance with the present invention is shown. In block 200, the testing programs starts to be executed in the firmware; in block 201, the firmware sends a first IDE command to write data to the IDE channel to be tested, wherein the data to be written is called “write-in data”; in block 202, the testing board 100 receives the first IDE command and data transferred from the IDE channel being tested, via the IDE interface 101; in block 203, the first IDE command is received by the decoder 103 via the control bus 105 and is converted by the decoder 103 to a write computing command, which is sent to the FIFO buffer 102, and the FIFO buffer 102 then gets the transferred data from the IDE interface 101 via the data bus 104, and stores the data temporarily; in block 204, the firmware sends a second IDE command to read data for the IDE channel to be tested, the testing board 100 receives the second IDE command, and the decoder 103 converts the second IDE command to a read computing command, which is sent to the FIFO buffer 102, and the testing board 100 then sends back data stored in the FIFO buffer 102 to the IDE channel to be tested; in block 205, the firmware reads data from the IDE channel being tested, which is called “read-from data”; and in block 206, the firmware compares the “write-in data” and the “read-from data”, and determines the testing outcome.

The execution of the testing programs branches at the block 206. In block 207, if the “write-in data” matches the “read-from data”, the firmware determines the tested IDE channel to be OK; in block 208, if the “write-in data” does not match the read-from data, the firmware determines the tested IDE channel to be bad. After the execution of the block 207 or block 208, the execution of the testing programs ends in block 209.

The simulation system and method for testing an IDE channel of the present invention does not need to use hard disk devices or computer operating systems. It only needs to connection of the tested board to the testing board 100, and starting the tested board for execution of the testing programs. Thus, the present invention provides a simple and low-cost simulation system and method for testing IDE channels.

The invention may be embodied in other specific forms without departing from its spirit or essential characteristics. The described embodiment is to be considered in all respects only as illustrative and not restrictive and the scope of the invention is, therefore, indicated by the appended claims rather than by the foregoing description. All changes which come within the meaning and range of equivalency of the claims are to be embraced within their scope.

What is claimed is:

1. A simulation system for testing IDE channels, comprising:
a tested board having at least an IDE chip with at least an IDE channel to be tested; and
a firmware having testing programs embedded therein, and the firmware is electrically connected to the tested board in advance; and
a testing board including at least an IDE interface for exchanging data with and receiving control signals from the tested board, a buffer for storing data temporarily, a decoder for decoding control signals, at least a data bus electrically connected between the IDE interface and the buffer, for transmitting data therebetween, and at least a control bus electrically connected between the IDE interface and the decoder, for transmitting control signals to the decoder;
wherein data transferred to and from the buffer is controlled by the decoder using write or read computing command sent from.

2. The simulation system as claimed in claim 1 wherein the buffer is a First-In First-Out (FIFO) buffer.

3. A simulation method for testing IDE channels, comprising the acts of:
providing a testing board having at least an IDE interface, a buffer, and a decoder for decoding IDE commands;
providing a tested board coupled to the testing board, the tested board having at least an IDE chip with IDE channels to be tested;
providing a firmware having testing programs embedded therein, the firmware is electrically connected to the tested board in advance; and
executing the testing programs.

4. The simulation method as claimed in claim 3 wherein the act of executing the testing programs comprises the acts of:
the firmware sending a first IDE command to write data from the IDE channel being tested, wherein the data to be written is called “write-in data”;
the testing board receiving both the first IDE command and the data transferred from the IDE channel being tested;
the transferred data being stored in the buffer;
the firmware sending a second IDE command to read data to the IDE channel to be tested, and the testing board receiving the second IDE command and sending back data stored in the buffer to the IDE channel being tested, which data is called “read-from data”;
the firmware reading the “read-from” data from the IDE channel being tested; and
the firmware comparing the “write-in data” and the “read-from data”, and determining the testing outcome.

5. The simulation method as claimed in claim 4 wherein the act of comparing the “write-in data” and the “read-from data” and determining the testing outcome comprises the acts of:
either determining that the “write-in data” matches the “read-from data”, therefore the IDE channel being tested is OK;
or determining that the “write-in data” does not match the “read-from data”, therefore the IDE channel being tested is bad.

6. The simulation method as claimed in claim 4 wherein the testing board exchanges data with and receives IDE commands from the tested board via the IDE interface.

7. The simulation method as claimed in claim 4 wherein the IDE commands are read or write computing commands, which are converted by the decoder, and are sent to the buffer.

8. The simulation method as claimed in claim 4 wherein the buffer is a FIFO buffer.

9. A method of testing IDE (Integrated Drive Electronics) channels, comprising:
providing IDE channels between opposite testing and tested boards;
writing data to a tested IDE channel under a command of a firmware;
transmitting said data to the testing board and stored in a first-in/first-out buffer of said testing board;
receiving a corresponding data from the testing board;
reading said corresponding data via said IDE channel; and
comparing said data and said corresponding data and determining said IDE channel is okay if said two data are matched.

10. The method as claimed in claim 9, wherein said firmware is provided by said tested board.
